(19) United States
(12) Patent Application Publication
(10) Pub. No.: US 2026/0231762 A1
(43) Pub. Date: Aug. 6, 2026

(54) POWER MODULE FOR SOLID-STATE CIRCUIT BREAKER

(71) Applicant: Zapadoceska univerzita v Plzni, Plzen (CZ)

(72) Inventors: Zdenek Peroutka, Plzen (CZ); Martin Jara, Plzen (CZ); Jan Reboun, Rokycany (CZ)

(21) Appl. No.: 19/152,074

(22) PCT Filed: Jan. 31, 2024
(86) PCT No.: PCT/CZ2024/050005

§ 371 Date: Jul. 30, 2025

(30) Foreign Application Priority Data
Jan. 31, 2023 (CZ) PV 2023-41

(51) Int. Cl. H10W 40/20; H10W 40/25

(52) U.S. Cl. CPC H10W 40/237; H10W 40/259

(57) ABSTRACT

A power module for a solid-state circuit breaker includes a heat sink (1) made of a dielectric material having thermal conductivity over 20 W/m/K provided on its surface with an electrically conductive power pattern (3). A bi-directional power electronics switch (5) is placed on the electrically conductive power pattern (3) and connected by an electrically conductive power connection (2). The electrically conductive power pattern (3) is interconnected with auxiliary dielectric substrates (9) on which electrically conductive non-power patterns (18) interconnecting non-power electronics circuits (7) are placed. At least the heat sink (1), the-power electronics switch (5), the auxiliary dielectric substrates (9), and the non-power electronics circuits (7) are jointly included in a monolithic multilayer structure elements of which are connected through entire contact surfaces. The heat sink (1) may be mechanically and thermally connected with an auxiliary heat sink (14) made of electrically conductive material having thermal conductivity over 180 W/m/K. Connection is made of a contact layer (20) compensating different coefficients of thermal expansion of the heat sink (1) and of the auxiliary heat sink (14).

### RELATED APPLICATION

This application is a national stage application under 35 U.S.C. § 371 of International Application No. PCT/CZ2024/050005, filed 31 Jan. 2024, which claims priority to Czech Patent Application No. PV 2023-41, filed 31 Jan. 2023, the disclosures of which are hereby incorporated by reference into the present application in their entirety.

### FIELD OF THE INVENTION

The present invention relates to a power module for solid-state circuit breakers. The power module comprises a power electronics circuit and non-power electronics devices, which provide an appropriate method for control of the power module components.

### BACKGROUND OF THE INVENTION

The fully solid-state circuit breakers belong to the technical field currently undergoing intense development, especially in the field of DC electrical circuits. This is related to a massive deployment of DC energy storages, DC distribution grids, and, last but not least, the expansion of the battery-supplied higher power applications. Here, the direct current protections and related circuit breakers improve the level of operation safety.

The fully solid-state DC circuit breaker is characterized by an absence of a mechanical switching apparatus. The function is conducted by a power electronics circuit with self-commutating power semiconductor devices, usually IGBT or MOSFET-type transistors that provide safe current tripping according to tripping characteristics of the circuit breaker.

Generally known topologies of the power electronics circuit for direct current tripping in both directions include, among others, a bridge rectifier with one transistor switch, an anti-serial connection of reverse conducting transistor switches, or an anti-parallel connection of reverse blocking transistor switches. Considering the required high nominal currents of the fully solid-state circuit breakers, it is necessary to arrange a certain number of transistors in parallel within one switch in order to achieve acceptable thermal loss under circuit breaker operation.

Document US2020/0365346 discloses a simple arrangement of a solid-state circuit breaker, to which a mechanical apparatus may be added, if galvanic load insulation is required for safety reasons. In this case the controlling section of the circuit breaker should provide a proper sequence of turning on and off both the mechanical apparatus and a power electronics circuit so that no current is loaded onto the mechanical apparatus upon turning on and tripping the circuit breaker. A controlling section shall also provide a proper control sequence when the circuit breaker is turned off manually. The power electronics circuit having bi-directional current tripping may be used in the circuit breaker not only to disconnect the load, i.e., to disconnect electrically conductive paths between mains input terminals and output terminals for a protected device, but it may also be used when circuit breaker tripping to produce an electrically conductive path between the mains input terminals. As disclosed in document US2021/0226441, the grid current flowing through this path causes the tripping of the superior protective device.

A power electronics circuit of a circuit breaker may be provided with discrete power semiconductor devices. The power electronic circuit may also be included in a power semiconductor module. Its structural components include a supporting base that provides a mechanical support to electronic components and permits dissipation of heat caused by power losses. Further included are electronic components for switching and creating a current pathway for a protected circuit, and electrically conductive patterns being created on at least one of the base surfaces and used for electrically conductive connection between the electronic components. For example, this solution is disclosed in document WO2009127179A1.

A common method for implementation of the power modules is use of the DBC technology. It is based on a ceramic substrate made from a material having high thermal conductivity while also providing electrical insulation. The substrate is provided with a copper layer fixed thereto using eutectic Cu and CuO₂ alloy on both sides. An electrically conductive pattern is etched in the copper layer. Etching of the pattern has a disadvantage with respect to wasting of materials, speed, and production safety. In addition, the etching method does not allow to achieve fine electrically conductive patterns. For example, this solution is disclosed in document KR20130139011A.

The ceramic substrate of the DBC technology may be layered by soldering to create sandwich structures. The power semiconductor bare dies may themselves be placed in a recess in the copper layer on a small ceramic substrate either individually or in small groups in a way to level up the upper side of the semiconductor bare die with the top side of the copper layer of the ceramic substrate. The bottom bare die electrode may be electrically connected to the lower side of the ceramic substrate via a passage in the ceramic substrate filled with a conductive material. The passage may be then used as a shunt resistor to measure the electric current. Each substrate may be put on a big ceramic substrate with the DBC technology according to requirements for total electric connection. Again, the need to use the copper layer thicker than thickness of the semiconductor bare die does not allow to achieve fine electrically conductive patterns, and the semiconductor bare dies fitted out like this do not use full surface of the ceramic substrate. For example, this solution is disclosed in document US2007/0138651.

Due to the high degree of parallelization of the transistors in the switch within the power electronics circuit topology of the circuit breaker, it is necessary to ensure optimum driving conditions (design symmetry, identical electrical parameters, minimization of parasitic inductances, etc.) for each individual transistor. Generally known approaches use non-power electronics devices very close to each transistor connected in parallel so that the impact of parasite elements in the commutation loop of the driving circuit is attenuated, in particular in dynamic phenomena in the power circuit.

Small dimensions of the non-power electronics devices require sufficiently fine electrically conductive pattern to be created correctly. The latter in a power module with a common substrate may not be feasible with etch-based technologies as the use of thick layers in the power circuit is required. In addition, the placement of the non-power electronics devices onto the same substrate with the power circuit limits the usable area of the power module surface for the electrically conductive patterns of the power circuit. This contributes to the increase of current density and power losses in the electrically conductive pattern of the power circuit. Also, the reduced surface of the electrically conductive pattern of the power circuit increases the power module's thermal resistance and the power module's internal operating temperature is increased thereby.

The object of the present invention is to provide a power module for the fully solid-state circuit breakers, which allows power loss (heat) dissipation to the maximum extent from the power circuit components, allows implementation of excellent construction design symmetry of the power circuit, contains non-power electronics devices for optimum driving conditions and protection of the power electronics switches, and which may be manufactured without etching with maximum level of details of electrically conductive patterns by the thick printed copper layer method known as TPC.

### SUMMARY OF THE INVENTION

The present invention relates to the construction design of a power module for a solid-state circuit breaker. The module includes an insulating material in which at least bi-directional power electronics switch and non-power electronics circuits are arranged. The insulating material may be placed in a package. Alternatively, the insulating material may be self-supporting and its surface operates as the package, or the material itself is the package. The function of the package is known in the art, and it includes in particular mechanical durability (impact resistance, abrasion resistance) and resistance to environmental influences. The insulating material is preferably a dielectric potting material.

The non-power electronics circuits include at least protective elements, circuits controlling the power electronics switch and circuits of the sensors. In addition, the module includes a dielectric material heat sink having thermal conductivity over 20 W/m/K. It can be made, for example, of aluminium nitride or other suitable ceramics with suitable thermal conductivity and expansion properties. The electrically conductive power pattern of copper, silver, or combination thereof, is applied directly on the heat sink and comprises at least two electrically insulated sections, and it is applied preferably using a method of additive deposition.

The bi-directional power electronics switch is placed on the electrically conductive power pattern and connected by an electrically conductive power connection. The power electronics switch comprises non-encapsulated power semiconductor bare dies mutually interconnected by a power conductive connection. The power electronics switch is located on longitudinal axis of the module. Favourably, the power electronics switch is placed in the exact centre; however, a small deviation defined by the fit-out width of the power electronics switch causes no significant deterioration of the properties. The centric mounting of the power electronics switch results in optimum use of the die area and minimized inductance of a commutation loop. The dies of the power electronics switch may be mounted either by soldering or sintering.

The electrically conductive power pattern is interconnected with output power electric terminals. Furthermore, the electrically conductive power pattern is interconnected with auxiliary dielectric substrates through a contact layer. There are electrically conductive non-power patterns of silver, copper, or combination thereof, placed on the auxiliary dielectric substrates to interconnect the non-power electronics circuits. Favourably, the non-power electric patterns are applied by additive technology. The non-power electronics circuits are interconnected with the output non-power electric terminals and with the power electronics switch via the non-power conductive connection.

Both the output power electric terminals and the output non-power electric terminals may be embodied as soldering pins, press-fit pins, or ultrasound-welded electrodes. The output power electric terminals and the output non-power electric terminals are conductively connected with the protective circuits (e.g., by soldering). In particular, the protective circuits protect against overheating of the module. In addition, hazardous overvoltage occurs upon turning the power electronics switch off, which is managed using the protective circuits as well (overvoltage protection). The protective circuits may comprise a varistor (MOV), or TVS, or an active overvoltage circuit.

Favourably, the protective circuits are placed on their own substrate and it may be a ceramic-based one. It may be a printed circuit board based on a glass-epoxide material. Favourably, the substrate is placed above the power electronics switch and forms a sandwich arrangement having a minimum commutation loop. Said structure may be implemented to create a fully integrated power module for a solid-state circuit breaker. Alternatively, the protective circuits may be located outside the power module. However, the fully integrated design of the circuit breaker is not attainable in this case.

At least the heat sink, the power electronics switch, the auxiliary dielectric substrates, and the non-power electronics circuits are jointly included in a monolithic multilayer structure, elements of which are connected through entire contact surfaces. The contact surfaces between the components are desirably continuous and flat so that they fit together well for efficient heat transfer.

For more efficient cooling of the power module, the heat sink may be mechanically and heat-conductively connected with an auxiliary heat sink made of electrically conductive material having heat conductivity over 180 W/m/K. The auxiliary heat sink may be made of aluminium, copper, or other metal or metal alloy. A contact layer eligible to compensate differential thermal expansivity properties of the heat sink and of the auxiliary heat sink is made as a connection.

The contact layer of the heat sink may be a multilayer one. The layer may comprise an electrically conductive layer applied on the heat sink, and an electrically conductive connection of which full contact surfaces interconnect the electrically conductive layer and the auxiliary heat sink in a monolithic way.

Analogically, according to the claimed invention, the contact layer of the auxiliary dielectric substrate is a multilayer. The layer comprises an electrically conductive layer applied on the auxiliary dielectric substrate, and electrically conductive power connection of which full contact surfaces interconnect the electrically conductive layer and the electrically conductive power pattern in a monolithic way.

A dielectric material of which the heat sink and/or auxiliary dielectric substrates are made, may be ceramics in particular. The electrically conductive power connection on the electrically conductive power pattern and/or electrically conductive connection of the auxiliary heat sink may be in particular a solder layer or a sintered material layer.

Favourably, the power electronics switch may be embodied either as comprising power semiconductor bare dies arranged in anti-serial order with reverse conducting transistor switches, or in an anti-parallel arrangement of reverse blocking transistor.

The power conductive connection between the power semiconductor bare dies of the bi-directional switch and/or the non-power conductive connection between the power semiconductor bare dies of the bi-directional switch and the non-power electronics circuit may comprise aluminium and/or copper wires and/or electrically conductive ribbons.

The object as defined above is achieved by the use of auxiliary substrates within the power module according to the present invention. The use of the auxiliary substrates will allow axially symmetrical arrangement because the conductive patterns for the transistor control and parameters sensing are made in above-crossing way.

### EXPLANATION OF DRAWINGS

The exemplary embodiment of the proposed invention is described with reference to the drawings, in which

FIG. 1 shows a cross-section view of a power module for fully solid-state circuit breaker with a heat sink made of a dielectric material;

FIG. 2 shows a cross-section view of a power module for fully solid-state circuit breaker with an auxiliary heat sink made of an electrically conductive material;

FIG. 3 shows layout of power module components on a heat sink—top view;

FIG. 4 shows placement of protective circuits on a substrate over a power electronics switch and non-power electronics circuits—top view.

### EXEMPLARY EMBODIMENT OF THE INVENTION

It is understood that specific embodiments of the invention described below are indicative only and do not in any way limit the embodiments of the invention to these specific ones shown here.

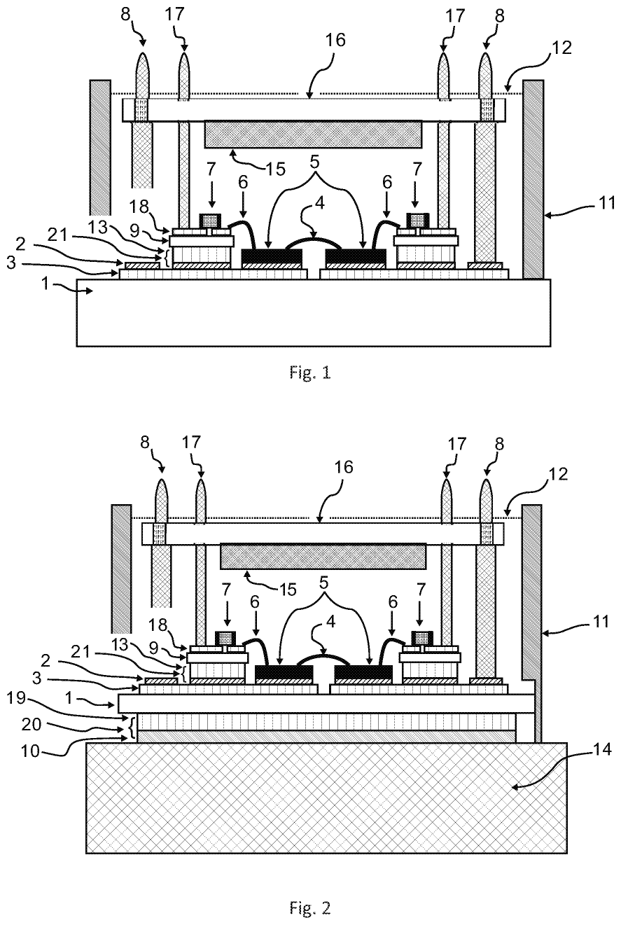

FIG. 1 shows the cross-section view on a power module of a fully solid-state circuit breaker. The power module for the solid-state circuit breaker includes insulating material 12. The insulating material 12 is placed in a package 11 made of a thermally resistant plastic. The insulating material 12 is a silicone dielectric gel.

In the insulating material 12 there is provided a bi-directional power electronics switch 5, non-power electronics circuits 7 including protective elements, circuits controlling the power electronics switch 5 and sensor circuits. Here, a desaturation protection is included in the protective elements. The sensor circuits are adapted to sensing of voltage, current, and temperature of the power electronics switch 5. In addition, the module includes a dielectric material heat sink 1 having thermal conductivity over 20 W/m/K. Aluminium nitride is suitable material for the heat sink 1. On its surface, the heat sink 1 is provided with an electrically conductive power pattern 3. An electrically conductive power pattern 3 comprises two electrically insulated sections. Owing to use of the dielectric material for the heat sink 1, the electrically conductive power pattern 3 is applied directly on the heat sink 1 and no electric insulation needs to be used between the electrically conductive power pattern 3 and the heat sink 1 being made of electrically conductive material in known designs.

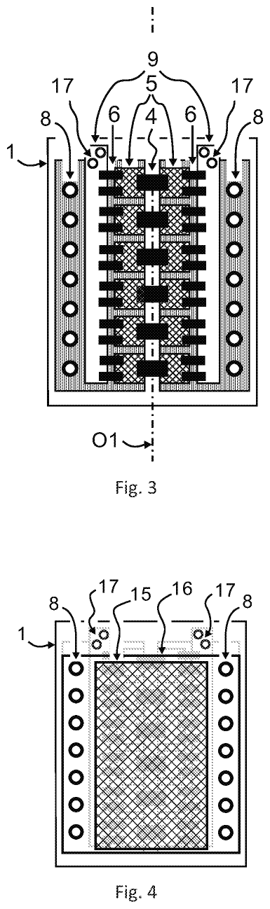

A bi-directional power electronics switch 5 is placed on the electrically conductive power pattern 3 and connected by an electrically conductive power connection 2. The bi-directional power electronics switch 5 comprises power semiconductor bare dies being mutually interconnected with a power conductive connection 4. The power electronics switch 5 is located on longitudinal axis O1 of the module. The power circuit comprises anti-serial arrangement of semiconductor bare dies of the power electronics switch 5. These are two groups of six of SiC MOSFET transistor dies connected in parallel, and they are placed axially symmetrically as closest as possible to the centre of the power module on the heat sink 1 as shown in FIG. 3 The electrically conductive power pattern 3 is interconnected with output power electric terminals 8. In addition, it is joined to the auxiliary dielectric substrates 9 via a contact layer 21. The contact layer 21 of the auxiliary dielectric substrate 9 comprises an electrically conductive layer 13 applied on the auxiliary dielectric substrate 9, and the electrically conductive power connection 2 of which full contact surfaces link the electrically conductive layer 13 and the electrically conductive power pattern 3 in a monolithic way. There are electrically conductive non-power patterns 18 placed on the auxiliary dielectric substrates 9. The non-power electric patterns 18 interconnect the non-power electronics circuits 7. The non-power electronics circuits 7 are interconnected with the output non-power electric terminals 17 and in addition, with the power electronics switch 5 via the non-power conductive connection 6. The heat sink 1, the power electronics switch 5, the auxiliary dielectric substrates 9, and the non-power electronics circuits 7 are jointly included in a monolithic multilayer structure elements of which are connected through entire contact surfaces.

Optimum control of the power electronics switch 5 bare dies arranged in parallel is provided by a suitable electric connection with the non-power electronics circuits 7. Thanks to thin layer of the electrically conductive non-power patterns 18 a necessary thin gap between the elements of the electrically conductive non-power pattern 18 is achieved allowing the use of the non-power electronics devices of SMD type with down to 0603 size. Here, the non-power electronics circuit 7 is used for symmetric and electrically identical driving of the transistors connected in parallel, for attenuation of undesired oscillations that occur by the power electronics circuit operation, or for protection of the gate electrodes of the transistors. Use of the auxiliary dielectric substrate 9 causes that a multilayer interconnection structure is formed. The structure allows full use of heat sink 1 obverse side to carry high current load by the electrically conductive power patterns 3 and axially symmetrical placement of the semiconductor bare dies of the power electronics switch 5 (refer to FIG. 3). At the same, the structure allows placement and interconnection of the non-power electronics circuit 7 on the auxiliary dielectric substrate 9 to be at distance as shortest as possible from the power electronics switch 5. The auxiliary dielectric substrates 9 have the quality of electric insulation, thermal expansion properties and thermal conductivity properties identical to the heat sink 1 and therefore, the resulting properties of the power module are not influenced in any way. In this example, balancing (protective) resistors of Gate and Source electrodes are placed on the auxiliary dielectric substrates 9 separately for each power semiconductor bare die. Use of the auxiliary dielectric substrate 9 permits maximization of the surface of the electrically conductive power pattern 3 on the heat sink 1. This is favourable, in particular with respect to minimization of the current density, minimization of power losses, and thermal impedance of the power module. At the same time, higher volume of the electrically conductive pattern 3 allow accumulation of more thermal energy in case of transient phenomena.

The output power electric terminals 8 and the output non-power electric terminals 17 are interconnected with the protective circuits 15 arranged on the substrate 16. The output terminals 8, 17 are provided as soldering pins.

The electrically conductive power pattern 3, the electrically conductive non-power patterns 18 and electrically conductive layer 13 of the auxiliary dielectric substrate 9 are applied by an additive technology (printing technique). As illustrated in FIG. 1, the electrically conductive power pattern 3 and the electrically conductive non-power patterns 18 have different thicknesses. The electrically conductive non-power pattern 18 is thinner than the electrically conductive power pattern 3. Thicknesses of the layers range from 20 μm to 300 μm.

The electrically conductive power connection 2 on the electrically conductive power pattern 3 and electrically conductive connection 10 of the auxiliary heat sink is a layer of solder. The power conductive connection 4 between the semiconductor bare dies of the bi-directional switch 5 and/or the non-power conductive connection 6 between the semiconductor bare dies of the bi-directional switch 5 and the non-power electronics circuit 7 are provided in the form of electrically conductive ribbons. More specifically, these are silver-plated copper ribbons. The power conductive connection 4 includes ribbons 4 mm wide and 200 μm thick. Compared to the wire-bonding technology, maximum transmitted current and reduction of the current density is permitted thereby not only in the power conductive connection 4 but also in the metallized area of the semiconductor bare die. The interconnection between the driving electrodes of the power electronics switch 5 bare dies and the non-power electronics circuit 7 is provided by 0.8 mm wide and 200 μm thick ribbons.

Another contemplated embodiment is shown in FIG. 2 and it differs from the one described above by that the dielectric material heat sink 1 is mechanically and thermally connected to the auxiliary heat sink 14 made of electrically conductive material having thermal conductivity over 180 W/m/K. A heat sink contact layer 20 is interconnecting the heat sink 1 and the auxiliary heat sink 14 while compensating their different thermal expansion properties. The contact layer 20 of the heat sink comprises an electrically conductive layer 19 applied on the heat sink 1, and an electrically conductive connection 10 of which full contact surfaces interconnect the electrically conductive layer 19 and the auxiliary heat sink 14 in a monolithic way. Here, the auxiliary heat sink 14 is made of aluminium, and the heat sink 1 is made of Al2O3. An advantage of this arrangement is lower price and lower demands on production technology.

### Industrial Applicability

A power module of a solid-state circuit breaker finds its use in power applications in industry, services, or research and development, and where electricity is used with the need for safe operation.

### LIST OF REFERENCE NUMERALS

1 dielectric material heat sink
2 electrically conductive power connection
3 electrically conductive power pattern
4 power conductive connection
5 power electronics switch
6 non-power conductive connection
7 non-power electronics circuit
8 output power electric terminals
9 auxiliary dielectric substrate
10 electrically conductive connection of auxiliary heat sink
11 package
12 insulating material
13 electrically conductive layer of auxiliary dielectric substrate
14 auxiliary heat sink made of electrically conductive material
15 protective circuits
16 substrate
17 output non-power electric terminals
18 electrically conductive non-power pattern
19 electrically conductive layer of the heat sink
20 heat sink contact layer
21 auxiliary dielectric substrate contact layer

1. A power module for a solid-state circuit breaker comprising:
an insulating material in which there is arranged a bi-directional power electronics switch and non-power electronics circuits with protective elements, circuits controlling the bi-directional power electronics switch and sensor circuits, further comprising a heat sink made of a dielectric material having thermal conductivity over 20 W/m/K, having on its surface an electrically conductive power pattern made of silver and/or copper, wherein the electrically conductive power pattern comprises at least two electrically insulated sections,
the bi-directional power electronics switch comprising power semiconductor bare dies mutually interconnected with a power conductive connection is placed on the electrically conductive power pattern and connected by thean electrically conductive power connection, wherein the bi-directional power electronics switch is positioned on longitudinal axis of the power module,
the electrically conductive power pattern is interconnected with output power electric terminals and via a contact layer further joined to auxiliary dielectric substrates where there are electrically conductive non-power patterns made of silver and/or copper interconnecting the non-power electronics circuits placed on the auxiliary dielectric substrates, wherein said contact layer of the auxiliary dielectric substrates comprises an electrically conductive layer applied on the auxiliary dielectric substrates, and the electrically conductive power connection of which full contact surfaces interconnect the electrically conductive layer and the electrically conductive power pattern in a monolithic way,
the non-power electronics circuits are interconnected with output non-power electric terminals and with the bi-directional power electronics switch via a non-power conductive connection,
the output power electric terminals and the output non-power electric terminals are interconnected with protective circuits,
wherein at least the heat sink, the bi-directional power electronics switch, the auxiliary dielectric substrates, and the non-power electronics circuits are jointly included in a monolithic multilayer structure, which parts are connected through entire contact surfaces.

2. The power module according to claim 1, wherein the heat sink is mechanically and thermally connected with an auxiliary heat sink made of electrically conductive material having thermal conductivity over 180 W/m/K by a contact layer to compensate different thermal expansion of the heat sink and of the auxiliary heat sink.

3. The power module according to claim 2, wherein the contact layer of the heat sink comprises an electrically conductive layer applied on the heat sink, and an electrically conductive connection of which full contact surfaces interconnect the electrically conductive layer and the auxiliary heat sink in a monolithic way.

4. The power module according to claim 1, wherein the heat sink and/or the auxiliary dielectric substrates are made of ceramics.

5. The power module according to claim 1, wherein the bi-directional power electronics switch comprises bare dies of reverse conducting transistors arranged in anti-serial connection, or bare dies with reverse blocking transistors arranged in anti-parallel connection.

6. The power module according to claim 1, wherein the electrically conductive power connection on the electrically conductive power pattern and/or electrically conductive connection of an auxiliary heat sink is a solder layer or a sintered material layer.

7. The power module according to claim 1, wherein the power conductive connection between the power semiconductor bare dies of the bi-directional power electronics switch and/or the non-power conductive connection between the bare dies of the bi-directional power electronics switch and the non-power electronics circuits is provided in the form of aluminium and/or copper wires and/or electrically conductive ribbons.

8. The power module according to claim 1, wherein the insulating material is placed in a package.

9. The power module according to claim 1, wherein the insulating material is self-supporting and is a package.
